(19) United States
(12) Patent Application Publication
(10) Pub. No.: US 2021/0123945 A1
(43) Pub. Date: Apr. 29, 2021

(54) VIBRATOR DEVICE

(71) Applicant: SEIKO EPSON CORPORATION, Tokyo (JP)

(72) Inventor: Masataka Kazuno, Kofu-shi (JP)

(21) Appl. No.: 17/081,257

(22) Filed: Oct. 27, 2020

(30) Foreign Application Priority Data
Oct. 29, 2019 (JP) 2019-195972

(51) Int. Cl. G01P 15/097; G01P 15/18; G01P 15/125; G01P 3/44

(52) U.S. Cl. CPC G01P 15/097; G01P 3/44; G01P 15/125; G01P 15/18

(57) ABSTRACT

A vibrator includes an electronic component that includes a base having a recess, a vibrator element that is arranged inside the recess, and a lid that is bonded to the base so that the vibrator element is accommodated between the base and the lid; a molded body covering the electronic component; an elastic member that is arranged between the lid and the molded body.

The present application is based on, and claims priority from JP Application Serial Number 2019-195972, filed Oct. 29, 2019, the disclosure of which is hereby incorporated by reference herein in its entirety.

### BACKGROUND

### 1. Technical Field

The present disclosure relates to a vibrator device.

### 2. Related Art

JP-A-2010-278186 describes a vibrator device in which an angular velocity sensor that detects an angular velocity around an X-axis, an angular velocity sensor that detects an angular velocity around a Y-axis and an angular velocity sensor that detects an angular velocity around a Z-axis are molded into a resin package in a state in which they are respectively fixed to leads. The angular velocity sensors include a package made of a resin package and a cap, as well as a vibrator element that is accommodated inside this package.

In this vibrator device as disclosed in JP-A-2010-278186, the three angular velocity sensors are molded together in a state in which they are arranged vertically and horizontally in a complex manner. For this reason, it is difficult to fill in the molten resin uniformly during the molding, and voids (air pockets) tend to occur at locations that are difficult to reach by the molten resin, such as in gaps between the mold and the angular velocity sensors or behind the angular velocity sensors. In order to suppress the occurrence of such voids, a method is conceivable in which the molding pressure when molding is increased, but if the molding pressure is increased, caps of the angular velocity sensors may warp due to the pressure they are subjected to by the molten resin, and there is the risk that the angular velocity sensors become defective or that the characteristics of the angular velocity sensors change.

### SUMMARY

According to a first aspect of the disclosure a vibrator device includes:

an electronic component comprising a base having a recess, a vibrator element that is arranged inside the recess, and a lid that is bonded to the base so that the vibrator element is accommodated between the base and the lid;

a molded body covering the electronic component; and

an elastic member that is arranged between the lid and the molded body.

According to another aspect of the present disclosure, a thickness at a center of the elastic member may be larger than a thickness at an edge of the elastic member.

According to another aspect of the present disclosure, a melting point of the elastic member may be higher than a melting point of a material constituting the molded body.

According to another aspect of the present disclosure, a Young's modulus of the elastic member may be lower than a Young's modulus of a material constituting the lid.

According to another aspect of the present disclosure, the elastic member may be made of silicone rubber.

According to another aspect of the present disclosure, the vibrator element may be a sensor element configured to detect a physical quantity.

According to another aspect of the present disclosure, the vibrator device may include a plurality of the electronic components.

### BRIEF DESCRIPTION OF THE DRAWINGS

The disclosure will be described with reference to the accompanying drawings, wherein like numbers reference like elements.

FIG. 1 is a perspective view showing a vibrator device.

FIG. 2 is a cross-sectional view showing an example of an electronic component.

FIG. 3 is a cross-sectional view showing an example of an electronic component.

FIG. 4 is a plan view showing an example of a molding method.

FIG. 5 is a cross-sectional view showing the deformation of a lid that occurs in a comparative configuration.

FIG. 6 is a cross-sectional view showing the deformation of a lid that occurs in a comparative configuration.

### DESCRIPTION OF EXEMPLARY EMBODIMENTS

Hereinafter, a vibrator device of one application example will be described in detail based on embodiments illustrated in the attached drawings.

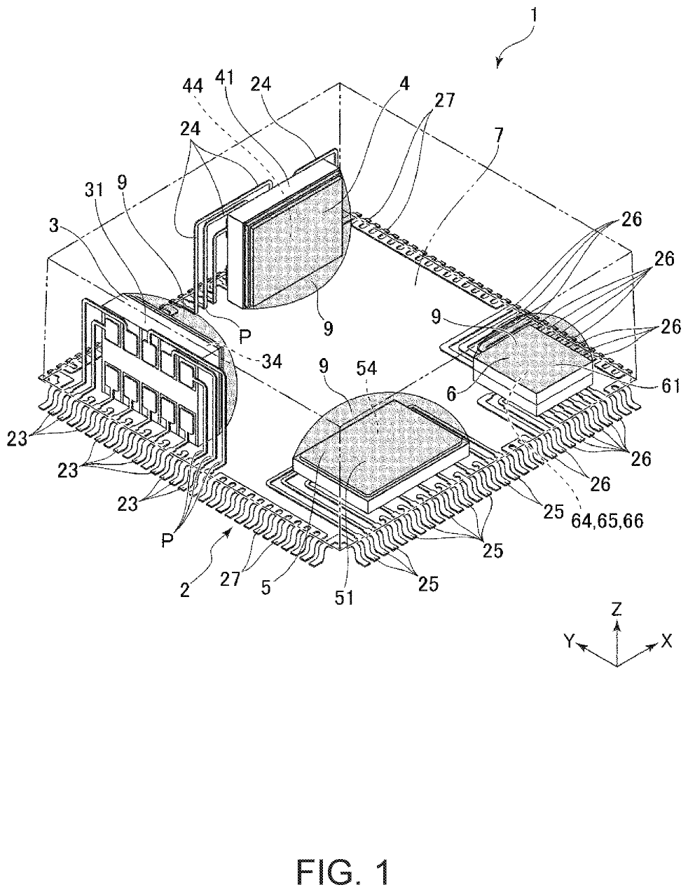

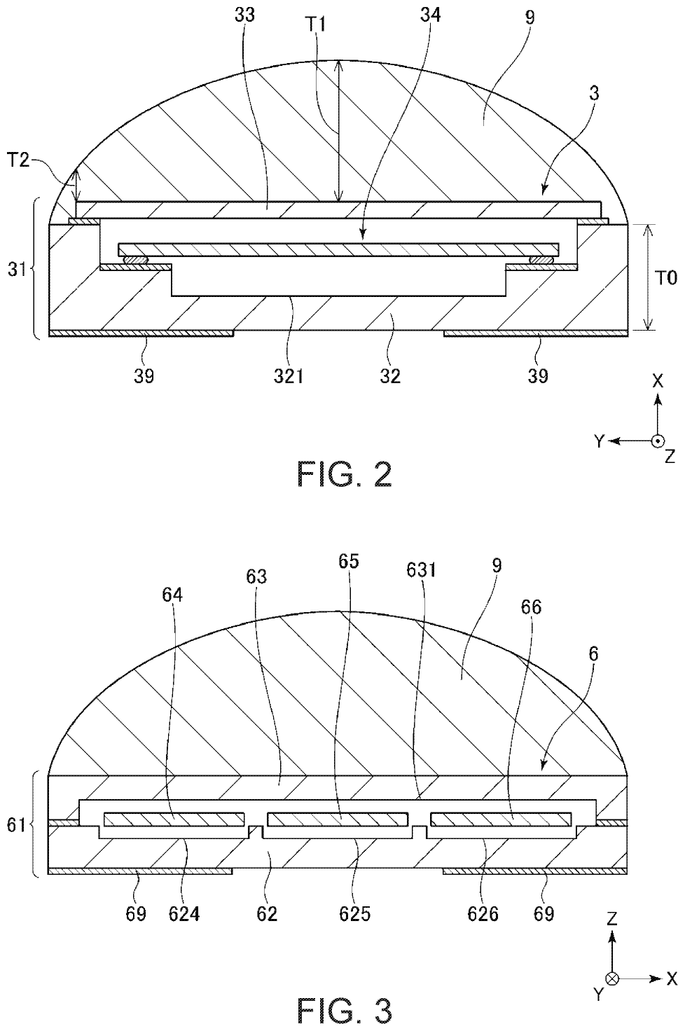

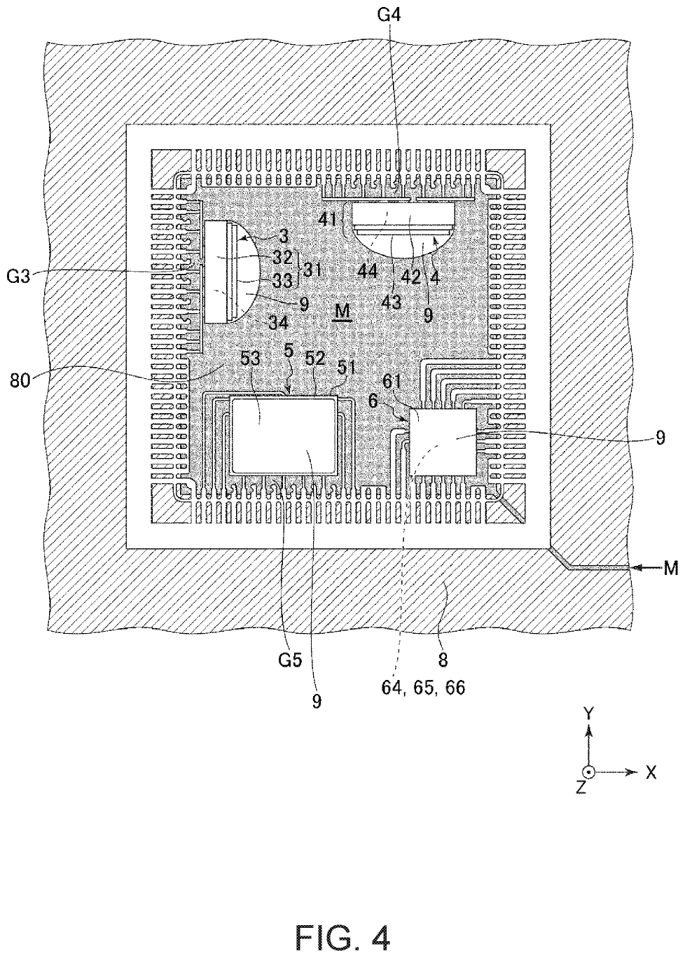

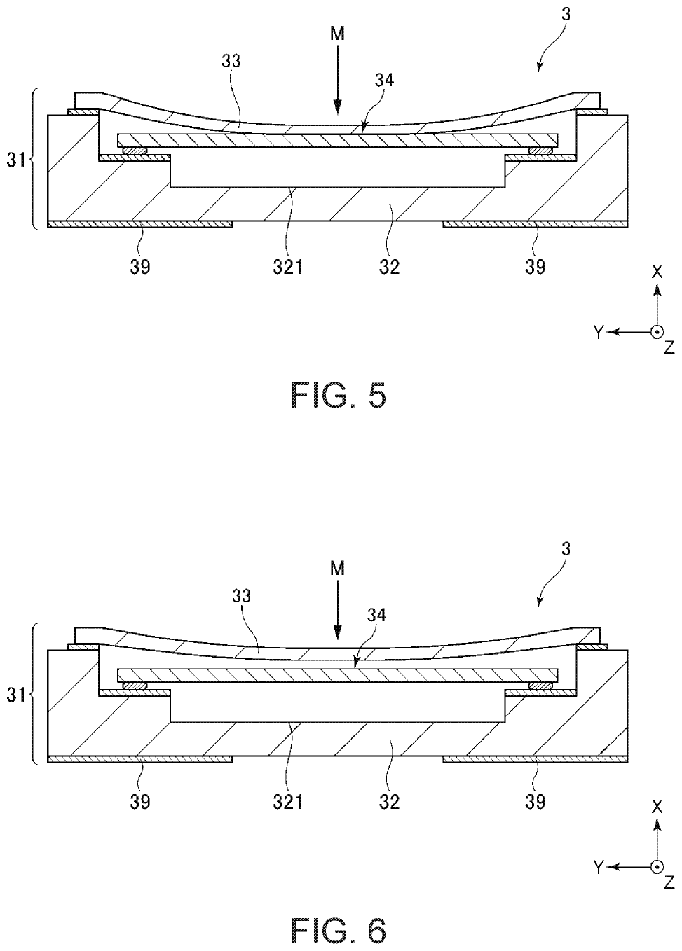

FIG. 1 is a perspective view showing a vibrator device. FIGS. 2 and 3 are both cross-sectional views showing examples of electronic components. FIG. 4 is a plan view showing an example of a molding method. FIGS. 5 and 6 are both cross-sectional views showing the deformation of a lid that occurs in comparative configurations.

For convenience of illustration, three axes, namely the X-axis, the Y-axis and the Z-axis, that are orthogonal to each other are shown in every drawing. Directions parallel to the X-axis are referred to as “X-axis direction”, directions parallel to the Y-axis are referred to as “Y-axis direction”, and directions parallel to the Z-axis are referred to as “Z-axis direction”. Furthermore, the side to which the arrows of these axes point may be referred to as the “plus side” and the opposite side may be referred to as the “minus side”. The plus side of the Z-axis direction may be referred to as “up” and the minus side of the Z-axis direction may be referred to as “down”.

A vibrator device 1 includes a lead group 2 including a plurality of leads 23 to 27, four electronic components 3, 4, 5 and 6 coupled to predetermined leads 23 to 27 out of the lead group 2, a mold body 7 into which the four electronic components 3, 4, 5 and 6 are molded, and elastic members 9 that are arranged between the electronic components 3, 4, 5 and 6 and the mold body 7.

The electronic components 3, 4, 5 and 6 are sensor components. More specifically, out of the electronic components 3, 4, 5 and 6, the electronic component 3 is an X-axis angular velocity sensor for detecting the angular velocity around the X-axis, the electronic component 4 is a Y-axis angular velocity sensor for detecting the angular velocity around the Y-axis, the electronic component 5 is a Z-axis angular velocity sensor for detecting the angular velocity around the Z-axis, and the electronic component 6 is a 3-axis acceleration sensor for independently detecting the acceleration in X-axis direction, the acceleration in Y-axis direction, and the acceleration in Z-axis direction. That is to say, the vibrator device 1 according to the present embodiment is a 6-axis compound sensor. Thus, by using the vibrator device 1 as a physical quantity sensor, it is possible to employ the vibration device 1 in a wide range of electronic devices, making it a vibrator device 1 with superior convenience, for which there is a high demand.

It should be noted that the configuration of the vibrator device 1 is not limited to this, and it is also possible to omit one, two or three of the electronic components 3, 4, 5 and 6, or to add other electronic components. Moreover, what the electronic components 3, 4, 5 and 6 measure is angular velocity and acceleration, but there is no limitation to this, and they may also measure e.g. pressure, temperature or the like. Furthermore, the electronic components 3, 4, 5 and 6 are not limited to sensor components and may also be vibrators, for example.

The following is a brief explanation of the electronic components 3, 4 and 5. The electronic components 3, 4 and 5 all have the same configuration, but their respective orientations are tilted by 90° with respect to each other, in accordance with their detection axes. For this reason, the following focuses on electronic component 3 as a representative example, and the explanation of electronic components 4 and 5 is omitted.

As shown in FIG. 2, the electronic component 3 includes a package 31 and a sensor element 34 serving as a vibrator element that is accommodated in the package 31. The package 31 includes a base 32 having a recess 321 on the inner side of which the sensor element 34 is arranged, and a lid 33 that is bonded to the base 32, closing the opening of the recess 321. The recess 321 is hermetically sealed in a depressurized atmosphere or in an atmosphere of an inert gas such as nitrogen. There is no particular limitation to the atmosphere inside the recess 321, and it may also be at atmospheric pressure or may be pressurized. A plurality of external terminals 39 are arranged on the lower side of the base 32, and these external terminals 39 are respectively coupled electrically to the sensor element 34. The base 32 is made of any of a variety of ceramics materials, such as alumina, titania or the like. The lid 33 is plate-shaped and is made of a metal material, such as Kovar or the like. However, there is no particular limitation to the material out of which the base 32 and the lid 33 are made.

The sensor element 34 is a quartz vibrator having, for example, drive arms and detection arms. If an angular velocity around the X-axis is applied in a state in which the drive arms are driven and caused to vibrate, a detection vibration is excited in the detection arms due to the Coriolis force, and it is possible to determine the angular velocity based on the charge that is generated in the detection arm by the detection vibration.

The foregoing explanations relate to the electronic component 3, but there is no particular limitation to the configuration of the electronic component 3, as long as it can display this functionality. For example, the sensor element 34 is not limited to a quartz vibrator, and may also be a silicon structure for example, or a configuration that detects the angular velocity based on changes in static capacitance. Furthermore, in the present embodiment, the electronic components 3, 4 and 5 have the same configuration, but there is no limitation to this, and it is also possible that at least one of them has a different configuration.

The following is a brief explanation of the electronic component 6. As shown in FIG. 3, the electronic component 6 includes a package 61 and three sensor elements 64, 65 and 66 that are accommodated in the package 61. The package 61 includes a base 62 and a lid 63. The base 62 has three recesses 624, 625 and 626 that are formed so that they are overlapped by the sensor elements 64, 65 and 66. The lid 63 has a recess 631 whose opening faces the base 62. The lid 63 is bonded to the base 62 with the sensor elements 64, 65 and 66 being accommodated in this recess 631. A plurality of external terminals 69 are arranged on the lower side of the base 62, and these external terminals 69 are electrically coupled to the sensor elements 64, 65 and 66. The base 62 and the lid 63 are both made of silicon, for example. However there is no particular limitation to the material out of which the base 62 and the lid 63 are made.

The sensor element 64 detects accelerations along the X-axis direction, the sensor element 65 detects accelerations along the Y-axis direction, and the sensor element 66 detects accelerations along the Z-axis direction. These sensor elements 64, 65 and 66 are silicone structures including fixed electrodes and movable electrodes, forming a static capacitance between the fixed electrodes and the movable electrodes. The movable electrodes can be displaced with respect to the fixed electrodes when an acceleration along the direction of the detection axis acts on them. In that case, it is possible to detect an acceleration in X-axis direction based on the change in static capacitance of the sensor element 64, to detect an acceleration in Y-axis direction based on the change in static capacitance of the sensor element 65, and to detect an acceleration in Z-axis direction based on the change in static capacitance of the sensor element 66.

The foregoing explanations relate to the electronic component 6, but there is no particular limitation to the configuration of the electronic component 6, as long as it can display this functionality. For example, the sensor elements 64, 65 and 66 are not limited to silicon structures and may also be quartz vibrators, and have a configuration that detects accelerations based on charges generated by vibration.

The following is an explanation of the lead group 2. As shown in FIG. 1, the lead group 2 includes a plurality of leads 23 that are coupled to the electronic component 3, a plurality of leads 24 that are coupled to the electronic component 4, a plurality of leads 25 that are coupled to the electronic component 5, a plurality of leads 26 that are coupled to the electronic component 6, and dummy leads 27 that are not coupled to any of the electronic components 3 to 6.

The leads 23 of the electronic component 3, the leads 24 of the electronic component 4, the leads 25 of the electronic component 5, and the leads 26 of the electronic component 6 are mechanically and electrically coupled through an electrically conductive bonding material such as solder, which is not shown in the drawings. Moreover, one end of the leads 23, 24, 25 and 26 protrudes out of the molded body 7, and they are coupled at this exposed portion to an object such as a circuit board.

The lead group 2 extends along the X-Y plane, which includes the X-axis and the Y-axis. In order to match the detection axis of the electronic component 3 with the X-axis, the leads 23 that are coupled to the electronic component 3 are bent by 90° towards the Z-axis direction at bending points P midway in the leads 23. Similarly, in order to match the detection axis of the electronic component 4 with the Y-axis, the leads 24 that are coupled to the electronic component 4 are bent by 90° towards the Z-axis direction at bending points P midway in the leads 24. By contrast, the leads 25 coupled to the electronic component 5 and the leads 26 coupled to the electronic component 6 are not bent like the leads 23 and 24, but extend in the X-Y plane only.

As shown in FIG. 1, the mold body 7 encases, i.e. seals in resin, the four electronic components 3, 4, 5 and 6, thus protecting them from moisture, dust, shocks and the like. There is no particular limitation to the mold material constituting the mold body 7, and it is possible to use, for example, a thermosetting epoxy resin, and the mold body 7 can be molded by transfer molding.

Here, the mold body 7 is formed by transfer molding in which the electronic components 3, 4, 5 and 6 are coupled to the lead group 2 and then arranged inside a molding die 8, a molten or softened molding material M is filled through a gate into the molding die 8, and then this molding material M is cured or hardened, covering the electronic components 3, 4, 5 and 6. However, since the four electronic components 3, 4, 5 and 6 are carefully arranged inside the molding die 8, i.e. within a cavity 80, the shape of the space within the molding die 8 is complex. Therefore, it is difficult to fill the molten or softened molding material M homogenously into the molding die 8. It is particularly difficult to fill the molding material M into narrow portions G3, G4 and G5 that are located on the rear side of the four electronic components 3, 4, 5 and 6 between the electronic components 3, 4, 5 and 6 and the side walls of the molding die 8, and there is the risk that voids (air pockets) occur at these locations, which may become a cause for worsening characteristics and breakage of the vibrator device 1.

In order to suppress the occurrence of such voids, a method is conceivable by which the molten or softened molding material M is filled into the molding die 8 at higher pressure. Thus, the molding material M can be filled more reliably even into locations that are difficult to fill with the molding material M, and the occurrence of voids can be effectively suppressed. However, with such a method, there is the risk that the lids 33, 43, 53 and 63 of the electronic components 3, 4, 5 and 6 are warped inward due to the pressure from the molding material M, and the electronic components 3, 4, 5 and 6 become defective or the characteristics of the electronic components 3, 4, 5 and 6 worsen.

To explain this with the electronic component 3 as a representative example, when the lid 33 warps inward, there is a risk that the airtightness of the package 31 breaks due to the stress caused by this and the vibration characteristics of the sensor element 34 change. Moreover, when the lid 33 warps inward, the resulting stress is transmitted to the sensor element 34, and there is the risk that the vibration characteristics of the sensor element 34 change.

Moreover, as shown in FIG. 5, there is the risk that the lid 33 comes into contact with the sensor element 34, and the sensor element 34 breaks or the sensor element 34 cannot be driven appropriately. Furthermore, as shown in FIG. 6, even if the lid 33 does not come into contact with the sensor element 34, when the lid 33 comes closes to the sensor element 34, a static capacitance is formed between the sensor element 34 and the lid 33 or the originally formed static capacitance changes. Thus, the characteristics of the sensor element 34 change, resulting in particular in zero-point drifting, so that the angular velocity detection characteristics of the electronic component 3 worsen. Here, “zero-point drifting” refers to the phenomenon that when a state in which no angular velocity (which is to be measured) is applied, there is a shift in the signal that is output at the zero point.

To address these problems, the elastic members 9 are arranged between the electronic components 3, 4, 5 and 6 and the molded body 7 in the vibrator device 1, in order to reduce the pressure on the electronic components 3, 4, 5 and 6 during molding, in particular the pressure that acts on a thin, lid 3 that tends to warp. The configuration of the elastic members 9 is the same in all cases, so that in the following, the elastic member 9 that is arranged between the electronic component 3 and the molded body 7 is explained as a representative example, and the explanation of the elastic members 9 that are arranged between the electronic components 4, 5 and 6 and the molded body 7 is omitted.

As shown in FIG. 2, an elastic member 9 is arranged on the lid 33 of the electronic component 3. This elastic member 9 has elasticity. More specifically, the elastic member 9 has elasticity at the molding temperature, for example at a temperature of 150° C. to 200° C. Therefore, when molding, the elastic member 9 undergoes elastic deformation and functions as a cushion, whereby the pressure acting on the lid 33 is reduced. For this reason, even if the molten or softened molding material M is filled at high pressure into the molding die 8, the above-described deformations of the lid 33 can be suppressed. Consequently, it is possible to suppress the occurrence of voids inside the molded body 7 while suppressing breakage and worsening of the characteristics of the electronic component 3, so that a vibrator device 1 with excellent reliability is attained.

The Young's modulus of the elastic member 9 is lower than the Young's modulus of the material constituting the lid 33. Thus, the elastic member 9 becomes softer than the lid 33, and the above-described effect is noticeably attained, namely the effect that the pressure acting on the lid 33 is reduced. It should be noted that there is no particular limitation on the Young's modulus of the material constituting the lid 33, and it may be, for example, 159 GPa in the case of Kovar. On the other hand, while there is no particular limitation on the Young's modulus of the elastic member 9, it may be for example not greater than 0.5 GPa, or not greater than 0.1 GPa, or not greater than 0.05 GPa. Thus, the elastic member 9 is sufficiently soft, and the above-described effect is noticeably attained, namely the effect that the pressure acting on the lid 33 is reduced.

Moreover, the melting point of the elastic member 9 is higher than that of the molding material M. Thus, it can be prevented that the elastic member 9 melts or softens during the molding, and a part or all of it comes off from the lid 33. Accordingly, the pressure acting on the lid 33 can be reduced more effectively and more reliably with the elastic member 9.

There is no particular limitation regarding the elastic member 9 and suitable examples include various types of rubber materials such as natural rubber, isoprene rubber, butadiene rubber, styrene-butadiene rubber, nitrile rubber, chloroprene rubber, butyl rubber, acrylic rubber, ethylene-propylene rubber, hydrin rubber, urethane rubber, silicone rubber, fluororubber, and various types of elastomers such as styrene-based, polyolefin-based, polyvinyl chloride-based, polyurethane-based, polyester-based, polyimide-based, polybutadiene-based, trans-polyisoprene-based, fluororubber-based, chlorinated polyethylene-based elastomers and the like. These can be used alone or in mixtures of two or more. Of these, silicone rubber may be used advantageously for the elastic member 9. By making the elastic member 9 of silicone rubber, the handling is easy and an elastic member 9 with sufficient elasticity is obtained.

In the present embodiment, the elastic member 9 covers substantially the entire lid 33. Therefore, the lid 33 is not touched by the molding material M and it is possible to reduce the pressure acting on the lid 33 effectively by the elastic member 9. However, there is no limitation to this, and it is also possible that a portion of the lid 33 is not covered by the elastic member 9.

Moreover, the elastic member 9 does not cover the side walls and the bottom wall of the package 31, that is, the surface of the base 32. As explained above, the base 32 is made of ceramics and has a sufficiently high strength. Consequently, it is able to sufficiently withstand high pressure during molding, even if it is not covered by the elastic member 9. Thus, by arranging the elastic member 9 only on the lid 33, that is, only on the necessary portions, it is possible to keep the elastic member 9 from becoming bloated. Therefore, it is possible to avoid that the protection of the electronic components 3, 4, 5 and 6 is compromised due to an excessive reduction of the amount of molding material M, and it can be avoided that the vibrator device 1 becomes too big due to ensuring a sufficient amount of the molding material M. However, there is no limitation to this, and it is also possible that the elastic material 9 covers at least a portion of the side walls and the bottom wall of the package 31.

Moreover, the elastic member 9 is dome-shaped, and its thickness T1 at its center is higher than its thickness T2 at its outer edge. Here, “center” refers to the center of the bonding face where the lid 33 is bonded to the elastic member 9, when viewed from the top. With such a shape, it is possible to efficiently disperse pressure applied during the molding within the elastic member 9, and the pressure acting on the lid 33 can be reduced more effectively. Moreover, since there is no corner in the elastic member 9, it hardly hampers the flow of the molding material M, and voids around the elastic member 9 can be effectively prevented. However, there is no particular limitation to the shape of the elastic member 9, and it may also be, for example, rectangular with T1=T2.

There is no limitation regarding the thickness T1 at the center of the elastic member 9, and if the thickness of the package 31 is taken to be T0, it may be 0.5≤T1/T0≤2.0, or 0.8≤T1/T0≤1.5, or 1.0≤T1/T0≤1.3. Thus, it is possible to ensure a sufficient deformation amount of the elastic member 9, so that the pressure acting on the lid 33 can be reduced more effectively. Moreover, it can be prevented that the elastic member 9 becomes too bloated, it is possible to avoid that the protection of the electronic components 3, 4, 5 and 6 is compromised due to an excessive reduction of the amount of molding material M, and it can be avoided that the vibrator device 1 becomes too big due to ensuring the amount of the molding material M.

The foregoing was an explanation of the vibrator device 1. As noted above, such a vibrator device 1 includes: an electronic component 3 including a base 32 having a recess 321; a sensor element 34 serving as a vibrator element that is arranged inside the recess 321; and a lid 33 that is bonded to the base 32 so that the sensor element 34 is accommodated between the base 32 and the lid 33; a molded body 7 covering the electronic component 3; an elastic member 9 that is arranged between the lid 33 and the molded body 7. With this configuration, the elastic member 9 deforms elastically and functions as a cushion at the time of molding to form the molded body 7, and thus, the pressure acting on the lid 33 is reduced. For this reason, deformations o the lid 33 can be suppressed, even if molding at high pressure. Consequently, it is possible suppress voids in the molded body 7 while avoiding defects and a deterioration of the characteristics of the electronic component 3, and a vibrator device 1 with superior reliability is obtained.

As explained above, a thickness T1 at a center of the elastic member 9 is larger than a thickness T2 at an edge of the elastic member 9. By providing the elastic members 9 with such a dome shape, it is possible to effectively disperse the pressure applied when molding inside the elastic members 9, and the pressure acting on the lid 33 can be reduced more effectively. Moreover, since there is no corner in the elastic member 9, it hardly hampers the flow of the molding material M, and voids around the elastic member 9 can be effectively prevented.

And as noted above, a melting point of the elastic member 9 is higher than a melting point of a molding material M constituting the molded body 7. Thus, it can be prevented that the elastic member 9 melts or softens during the molding, and a part or all of it comes off from the lid 33. Accordingly, the pressure acting on the lid 33 can be reduced more effectively and more reliably with the elastic member 9.

And as noted above, a Young's modulus of the elastic member 9 is lower than a Young's modulus of a material constituting the lid 33. Thus, the elastic member 9 becomes softer than the lid 33 and it is possible to reduce the pressure acting on the lid 33.

And as noted above, the elastic member 9 is made of silicone rubber. Thus, handling becomes easy and an elastic member 9 with sufficient elasticity is attained.

And as noted above, the vibrator element is a sensor element 34 configured to detect a physical quantity, in particular a sensor element 34 to detect an angular velocity as in the present embodiment. Thus, it is possible to apply the vibrator device 1 to sensors for physical quantity. Therefore, it is possible to employ the vibration device 1 in a wide range of electronic devices, making it a vibrator device 1 with superior convenience, for which there is a high demand. Moreover, it is possible to suppress zero-point drift of the sensor 34.

And as noted above, the vibrator device 1 includes a plurality of the electronic components 3, 4, 5 and 6. Thus, a vibrator device 1 with even greater convenience can be attained. Moreover, the greater the number of electronic parts, the higher is the tendency that the form of the space inside the molding die 8 becomes complex and voids occur. For this reason, the vibrator device 1 can attain the above-explained effects even more noticeably. Furthermore, it is possible to suppress zero-point drift of the sensor elements 34.

The vibrator device of the disclosure has been described above based on the illustrated embodiments, but the disclosure is not limited thereto, and the configurations of the units can each be replaced by any configuration having a similar function. Also, other constituent element may be added to the disclosure. Also, the embodiments may be appropriately combined with each other.

What is claimed is:

1. A vibrator device comprising:
an electronic component comprising a base having a recess, a vibrator element that is arranged inside the recess, and a lid that is bonded to the base so that the vibrator element is accommodated between the base and the lid;
a molded body covering the electronic component; and
an elastic member that is arranged between the lid and the molded body.

2. The vibrator device according to claim 1, wherein a thickness at a center of the elastic member is larger than a thickness at an edge of the elastic member.

3. The vibrator device according to claim 1, wherein a melting point of the elastic member is higher than a melting point of a material constituting the molded body.

4. The vibrator device according to claim 1, wherein a Young's modulus of the elastic member is lower than a Young's modulus of a material constituting the lid.

5. The vibrator device according to claim 1, wherein the elastic member is made of silicone rubber.

6. The vibrator device according to claim 1, wherein the vibrator element is a sensor element configured to detect a physical quantity.

7. The vibrator device according to claim 1, including a plurality of the electronic components.
